(19) United States
(12) Patent Application Publication
(10) Pub. No.: US 2008/0265343 A1
(43) Pub. Date: Oct. 30, 2008

(54) FIELD EFFECT TRANSISTOR WITH INVERTED T SHAPED GATE ELECTRODE AND METHODS FOR FABRICATION THEREOF

(75) Inventors: Brian J. Greene, Yorktown Heights, NY (US); William F. Clark, Essex Junction, VT (US); Bruce B. Doris, Brewster, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/740,442

(22) Filed: Apr. 26, 2007

(51) Int. Cl. H01L 29/772

(52) U.S. Cl. 257/412; 438/294; 257/E29.264; 257/E21.409

(57) ABSTRACT

A semiconductor structure includes an inverted T shaped gate electrode located over a channel region that separates a plurality of source and drain regions within a semiconductor substrate. The inverted T shaped gate electrode may comprise different gate electrode materials in a horizontal portion thereof and a vertical portion thereof. The semiconductor structure may be passivated with an inter-level dielectric (ILD) layer through which may be located and formed a plurality of vias that contact the plurality of source and drain regions. Due to the inverted T shaped gate electrode, the semiconductor structure exhibits a reduced gate electrode to via capacitance.

### BACKGROUND

1. Field of the Invention

The invention relates generally to semiconductor structures. More particularly, the invention relates to semiconductor structures with enhanced performance.

2. Description of the Related Art

Semiconductor structures include both active devices such as diodes and transistors, and passive devices such as resistors and capacitors. The active devices and the passive devices are connected and interconnected using patterned conductor layers that are separated by dielectric layers.

As semiconductor technology has advanced, and semiconductor structure and semiconductor device dimensions have decreased, various novel effects may become more pronounced when fabricating semiconductor structures. One particular novel effect that may compromise operation of a semiconductor device is a short channel effect that results from inadequate control of a gate electrode over a channel region within a semiconductor device. Other particular novel effects that may compromise operation of a semiconductor device include gate to source and drain region capacitive effects and gate to contact stud (i.e., contact via) capacitive effects.

The gate to source and drain region capacitive effects and gate to contact stud capacitive effects are undesirable insofar as such capacitive effects contribute to a resistance-capacitance time delay within a particular semiconductor structure that includes a particular semiconductor device. Resistance-capacitance time delays are in general undesirable within semiconductor device fabrication insofar as resistance-capacitance time delays lead to non-optimal performance of semiconductor devices within semiconductor structures.

Semiconductor structure and semiconductor device dimensions are certain to continue to decrease as semiconductor technology advances. Thus, desirable are semiconductor structures and semiconductor devices with enhanced performance, in particular with regard to attenuated gate to source and drain region capacitive effects and gate to contact stud capacitance effects.

### SUMMARY

The invention includes a semiconductor structure and a plurality of methods for fabricating the semiconductor structure. The semiconductor structure in accordance with the invention comprises a semiconductor device that includes a gate electrode that has an inverted T shape. Within the context of the invention, an ‘inverted T shape’ is intended as a conventional T shape that has been rotated 180° through a horizontal axis. As a result of such rotation, a horizontal portion of an ‘inverted T shape’ is connected to a bottom of a vertical portion of the ‘inverted T shape’ rather than the top of the vertical portion, as in a conventional T shape. Furthermore, the horizontal bottom portion extends beyond the edges of the vertical portion. The methods in accordance with the invention are directed towards fabricating the semiconductor structure that comprises the semiconductor device that includes the gate electrode that has the inverted T shape. The inverted T shape of the gate electrode provides for attenuated gate to source and drain region capacitive effects and attenuated gate to contact stud capacitive effects within semiconductor structures fabricated in accordance with the invention.

A semiconductor structure in accordance with the invention includes a gate electrode located over a channel region that separates a plurality of source and drain regions within a semiconductor substrate. The gate electrode has an inverted T shape.

A particular method for fabricating a semiconductor structure in accordance with the invention includes providing a second gate electrode material layer aligned with a first gate electrode material layer different from the second gate electrode material layer over a semiconductor substrate. The method also includes thinning the second gate electrode material layer with respect to the first gate electrode material layer to provide an inverted T shaped gate electrode from a thinned second gate electrode material layer and the first gate electrode material layer. The method also includes forming into the semiconductor substrate while using the inverted T shaped gate electrode as a mask a plurality of source and drain regions.

Another particular method for fabricating a semiconductor structure in accordance with the invention includes providing a patterned second gate electrode material layer upon a first gate electrode material layer different from the patterned second gate electrode material layer over a semiconductor substrate. The method also includes forming a spacer adjoining the patterned second gate electrode material layer. The method also includes etching the first gate electrode material layer while using the patterned second gate electrode material layer and the spacer as a mask to provide an inverted T shaped gate electrode from the patterned second gate electrode material layer and a patterned first gate electrode material layer patterned from the first gate electrode material layer. The method also includes forming into the semiconductor substrate while using at least the inverted T shaped gate electrode as a mask a plurality of source and drain regions.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, that form a material part of this disclosure, wherein:

FIG. 1 to FIG. 5 show a series of schematic cross-sectional diagrams illustrating the results of progressive stages in fabricating a semiconductor structure in accordance with a particular embodiment of the invention.

FIG. 6 to FIG. 10 show a series of schematic cross-sectional diagrams illustrating the results of progressive stages in fabricating a semiconductor structure in accordance with another embodiment of the invention.

### DESCRIPTION OF THE PREFERRED EMBODIMENT

The invention, which includes a semiconductor structure and related methods for fabricating the semiconductor structure, is understood within the context of the description that follows. The description that follows is understood within the context of the drawings described above. Since the drawings are intended for illustrative purposes, the drawings are not necessarily drawn to scale.

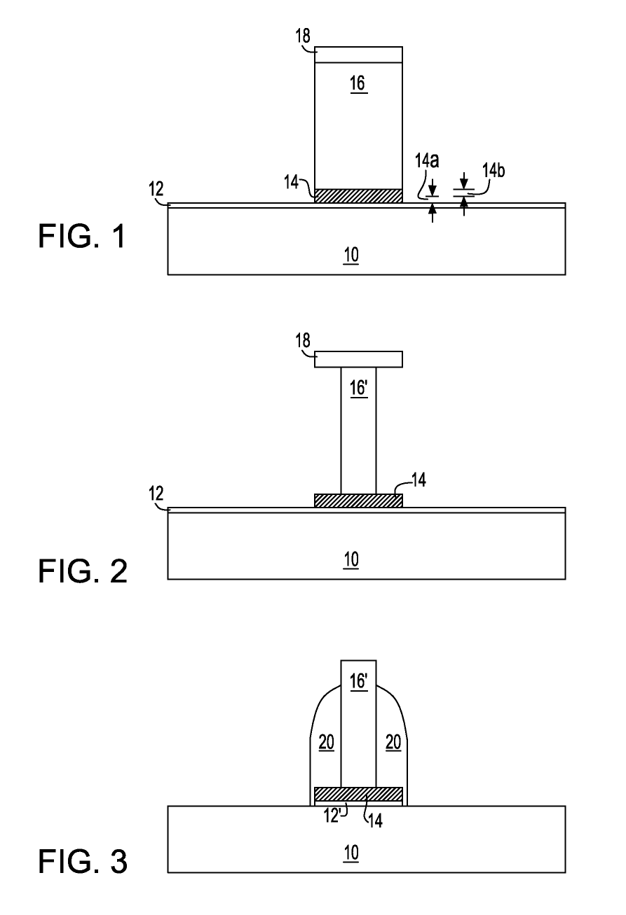

FIG. 1 to FIG. 5 show a series of schematic cross-sectional diagrams illustrating the results of progressive stages in fabricating a semiconductor structure in accordance with a particular embodiment of the invention. This particular embodiment of the invention comprises a first embodiment of the invention.

FIG. 1 shows a semiconductor substrate 10. A gate dielectric 12 is located upon the semiconductor substrate 10. A first gate electrode material layer 14 is located upon the gate dielectric 12. A second gate electrode material layer 16 is located upon the first gate electrode material layer 14. A capping layer 18 is located upon the second gate electrode material layer 16.

Each of the foregoing semiconductor substrate 10 and overlying layers 12, 14, 16 and 18 may comprise materials, have dimensions and be formed using methods that are otherwise generally conventional in the semiconductor fabrication art.

The semiconductor substrate 10 may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a conventional thickness.

Although the instant embodiment illustrates the invention within the context of a semiconductor substrate 10 that comprises a bulk semiconductor substrate, neither the embodiment nor the invention is necessarily so limited. Rather, the embodiment and the invention also alternatively contemplate the use of a semiconductor-on-insulator (SOI) substrate. Such a semiconductor-on-insulator (SOI) substrate typically comprises a base semiconductor substrate, a buried dielectric layer located upon the base semiconductor substrate and a surface semiconductor layer located upon the buried dielectric layer. Similarly, the embodiment and the invention also contemplate the use of a hybrid orientation (HOT) substrate. A hybrid orientation substrate includes multiple semiconductor regions with different crystallographic orientations.

The gate dielectric 12 may comprise conventional dielectric materials such as oxides, nitrides and oxynitrides of silicon that have a dielectric constant from about 4 (i.e., typically a silicon oxide) to about 8 (i.e., typically a silicon nitride), measured in vacuum. Alternatively, the gate dielectric 12 may comprise generally higher dielectric constant dielectric materials having a dielectric constant from about 8 to at least about 100. Such higher dielectric constant dielectric materials may include, but are not limited to hafnium oxides, hafnium silicates, zirconium oxides, lanthanum oxides, titanium oxides, barium-strontium-titanates (BSTs) and lead-zirconate-titanates (PZTs). The gate dielectric 12 may be formed using any of several methods that are appropriate to its material of composition. Non-limiting examples include thermal or plasma oxidation or nitridation methods, chemical vapor deposition methods (including atomic layer deposition methods) and physical vapor deposition methods. Typically, the gate dielectric 12 comprises a thermal silicon oxide dielectric material that has a conventional thickness that may be in a range from about 10 to about 70 angstroms.

The first gate electrode material layer 14 may comprise a metal containing material such as but not limited to a titanium metal, a tantalum metal or a tungsten metal, or an alloy thereof. Alternatively a silicide of the foregoing metals or a nitride of the foregoing metals may also be used. Any of the foregoing materials may be formed using generally conventional methods. Such methods may include, but are not necessarily limited to, plating methods, chemical vapor deposition methods and physical vapor deposition methods. The first gate electrode material layer 14 is typically formed of a material that is selected predicated upon a desirable work function for the first gate electrode material layer 14. Typically, the first gate electrode material layer 14 has a generally conventional thickness from about 100 to about 300 angstroms.

The second gate electrode material layer 16 will typically comprise a gate electrode material different than at least the top portion of the first gate electrode material layer 14. Thus, the second gate electrode material layer 16 will typically comprise other than a metal, metal nitride or metal silicide. Candidate materials for the second gate electrode material layer 16 include a doped polysilicon material or a doped polysilicon-germanium alloy material (i.e., having a dopant concentration from about 1e18 to about 1e22 dopant atoms per cubic centimeter). The foregoing materials may also be formed using any of several methods. Non-limiting examples include chemical vapor deposition methods and physical vapor deposition methods, such as, but not limited to evaporative methods and sputtering methods. Typically, the second gate electrode material layer 16 comprises a doped polysilicon material that has a generally conventional thickness from about 500 to about 1500 angstroms.

As is illustrated within the schematic cross-sectional diagram of FIG. 1, the embodiment also contemplates that the first gate electrode material layer 14 may comprise a bilayer comprising a lower lying layer 14a and an upper lying layer 14b located and formed upon the lower lying layer 14a. Under such circumstances, the lower lying layer 14a is intended as comprising a polysilicon or polysilicon-germanium alloy material analogous, equivalent or identical to the polysilicon or polysilicon-germanium alloy from which is comprised the second gate electrode material layer 16. Such an upper lying layer 14b comprises a metal material analogous, equivalent or identical to the metal material from which is comprised the first gate electrode material layer 14.

The capping layer 18 comprises a capping material that in turn typically comprises a hard mask material. Dielectric hard mask materials are most common but by no means limit the instant embodiment or the invention. Non-limiting examples of hard mask materials include oxides, nitrides and oxynitrides of silicon. Oxides, nitrides and oxynitrides of other elements are not excluded. The capping material may be formed using any of several methods that are conventional in the semiconductor fabrication art. Non-limiting examples include chemical vapor deposition methods and physical vapor deposition methods. Typically, the capping layer 18 comprises a silicon nitride capping material that has a generally conventional thickness from about 100 to about 500 angstroms.

FIG. 2 shows a second gate electrode material layer 16′ that results from laterally etching the second gate electrode material layer 16 that is illustrated in FIG. 1 while using the capping layer 18 and the first gate electrode material layer 14 as vertical etch stop layers. The foregoing etching may be effected while using an anisotropic etchant that may comprise either a plasma etchant or a wet chemical etchant. Typically, each side of the second gate electrode material layer 16 is undercut beneath the capping layer 18 by an undercut distance of about one-third a linewidth of the capping layer 18. Typically, a linewidth of the capping layer 18, the second gate electrode material layer 16 and the first gate electrode material layer 14 comprises a minimum photolithographically resolvable linewidth.

FIG. 3 first shows the results of stripping the capping layer 18 from the semiconductor structure of FIG. 2. The capping layer 18 may be stripped using methods and materials that are appropriate to a material of composition of the capping layer 18. Wet chemical etch methods, as well as selective dry plasma etch methods, may be used.

FIG. 3 next shows the results of patterning the gate dielectric layer 12 to form a gate dielectric layer 12′ while using the first gate electrode material layer 14 as an etch mask layer. The foregoing patterning may also be effected while using wet chemical etch methods, as well as selective dry plasma etch methods, that are conventional in the semiconductor fabrication art.

FIG. 3 finally shows a spacer 20 located and formed covering sidewalls of the second gate electrode material layer 16′, the first gate electrode material layer 14 and the gate dielectric 12′. Although the spacer 20 is illustrated as a plurality of layers in cross-sectional view, the spacer 20 is intended as a single contiguous layer surrounding the second gate electrode material layer 16′, the first gate electrode material layer 14 and the gate dielectric 12′ in plan-view.

The spacer 20 typically comprises a dielectric spacer material. Similarly with other dielectric structures within the instant embodiment, candidate dielectric spacer materials again include oxides, nitrides and oxynitrides of silicon. Also again, oxides, nitrides and oxynitrides of other elements are not excluded. The spacer 20 is formed using a blanket layer deposition and anisotropic etchback method that uses an anisotropic etching plasma for etching purposes.

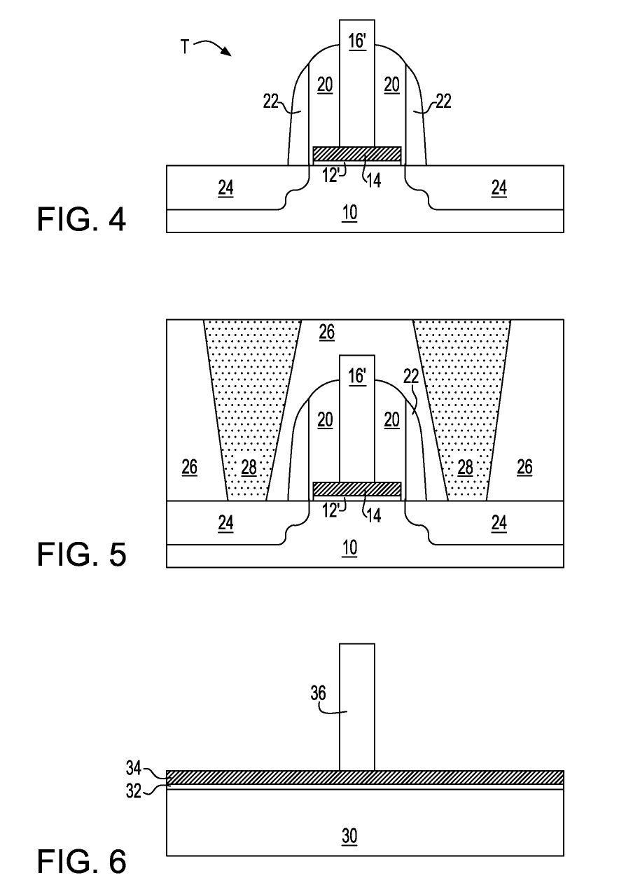

FIG. 4 shows a second spacer 22 located and formed adjoining a sidewall of the spacer 20. The second spacer 22 may be formed using methods and materials generally analogous, equivalent or identical to the methods and materials used for forming the spacer 20. However, the second spacer 22 will typically comprise a spacer material that is different from the spacer material from which is comprised the spacer 20, to thus allow for selective etching when forming the second spacer 22 located and formed upon the sidewall of the spacer 20.

FIG. 4 finally shows a plurality of source and drain regions 24 located and formed within the semiconductor substrate 10 and separated by the first gate electrode material layer 14, to thus provide a completed transistor T. As is understood by a person skilled in the art, the plurality of source and drain regions 24 is formed using a two-step ion implantation method. A first step within the two-step ion implantation method uses the first gate electrode material layer 14, the second gate electrode material layer 16′ and the spacer 20, but absent the second spacer 22, as a mask. A second step within the two-step ion implantation method uses the first gate electrode material layer 14, the second gate electrode material layer 16′, the spacer 20 and the second spacer 22 as a mask. Dopant concentrations within the source and drain regions 24 are provided at generally conventional levels. Dopant concentrations within extension region portions of the source and drain regions 24 may under certain circumstances be at lower levels than dopant concentrations within contact region portions of the source and drain regions. Such differential doping concentrations are, however, not a limitation of the embodiment or of the invention.

FIG. 5 first shows an inter-level dielectric (ILD) layer 26 located covering the semiconductor structure whose schematic cross-sectional diagram is illustrated in FIG. 4, including in particular the transistor T structure. A plurality of apertures is located through the inter-level dielectric (ILD) layer 26 to access the plurality of source and drain regions 24. The inter-level dielectric (ILD) layer 26 whose schematic cross-sectional diagram is illustrated in FIG. 5 may comprise any of several dielectric materials. Included in particular, but also not limiting, are oxides, nitrides and oxynitrides of silicon. Oxides, nitrides and oxynitrides of other elements are not excluded. Also not excluded are generally higher dielectric constant inter-level dielectric (ILD) materials (i.e., having a dielectric constant greater than about 4.0) and generally lower dielectric constant inter-level dielectric (ILD) materials (i.e., having a dielectric constant less than about 4.0). Such generally lower dielectric constant inter-level dielectric (ILD) materials include spin-on-glass (SOG) materials, spin-on-polymer (SOP) materials, nanoporous materials, microporous materials, carbon doped materials and fluorine doped materials. The foregoing materials may be deposited using any of several methods that are conventional in the semiconductor fabrication art. Included in particular, but also not limiting, are thermal or plasma oxidation or nitridation methods, spin-coating methods, chemical vapor deposition methods and physical vapor deposition methods.

FIG. 5 also shows a plurality of vias 28 (i.e., contact studs) located within the plurality of apertures that are formed through the inter-level dielectric (ILD) layer 26 to access the plurality of source and drain regions 24. The vias 28 comprise a conductor material. Candidate conductor materials include any of several, metals, metal alloys, metal silicides, metal nitrides, as well as doped polysilicon materials and polycide materials. Particularly common, but by no means limiting the invention, are vias 28 that comprise a tungsten conductor material. The vias may be formed using any of several methods. Included in particular are chemical vapor deposition methods, physical vapor deposition methods and plating methods. Typically, the vias 28 are formed using an appropriate deposition method that provides a blanket layer of a via conductor material that is subsequently planarized. Any of several planarization methods may be used. Mechanical planarizing methods and chemical mechanical polish planarizing methods are common.

FIG. 5 shows a schematic cross-sectional diagram of a semiconductor structure in accordance with a particular embodiment of the invention that comprises a first embodiment of the invention. The semiconductor structure includes a transistor (i.e., a planar field effect transistor) that comprises a gate electrode 14/16′ that has an inverted T shape. Such a gate electrode with the inverted T shape provides for reduced gate 14/16′ to contact via 28 capacitance or reduced gate 14/16′ to source and drain region 24 capacitance within the semiconductor structure.

FIG. 6 to FIG. 9 show a series of schematic cross-sectional diagrams illustrating the results of progressive stages in fabricating a semiconductor structure in accordance with another embodiment of the invention. This other embodiment of the invention comprises a second embodiment of the invention. FIG. 6 shows a schematic cross-sectional diagram of the semiconductor structure at an early stage in the fabrication thereof in accordance with this second embodiment.

FIG. 6 shows a semiconductor substrate 30. A gate dielectric 32 is located upon the semiconductor substrate 30. A first gate electrode material layer 34 is located upon the gate dielectric 32. A second gate electrode material layer 36 is located upon the first gate electrode material layer 34.

Within this second embodiment: (1) the semiconductor substrate 30 corresponds with the semiconductor substrate 10 within the first embodiment as illustrated in FIG. 1; (2) the gate dielectric 32 corresponds with the gate dielectric 12 within the first embodiment as illustrated in FIG. 1; (3) the first gate electrode material layer 34 corresponds with the first gate electrode material layer 14 within the first embodiment as illustrated in FIG. 1; and (4) the second gate electrode material layer 36 corresponds with the second gate electrode material layer 16 within the first embodiment as illustrated in FIG. 1. As is understood by a person skilled in the art, the second gate electrode material layer 36 that is illustrated in FIG. 6 may of necessity be formed of a minimal photolithographically resolvable linewidth, and for that reason a gate electrode linewidth of a transistor fabricated in accordance with the second embodiment of the invention may of necessity be greater than a gate electrode linewidth of a transistor fabricated in accordance with the first embodiment of the invention.

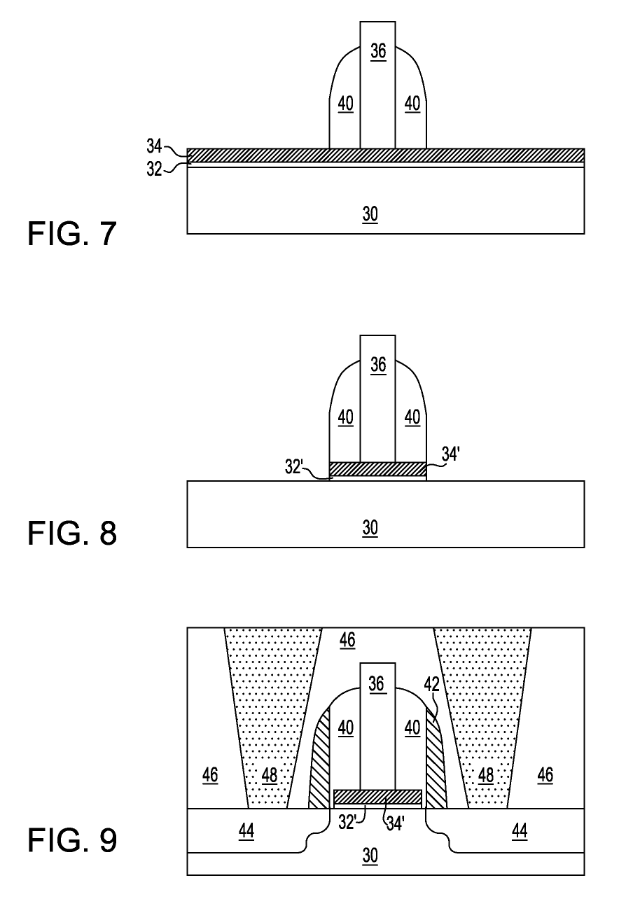

FIG. 7 shows a spacer 40 located adjoining the sidewalls of the second gate electrode material layer 36. Similarly with the spacer 20 within the first embodiment of the invention as illustrated in FIG. 3, the spacer 40 is also intended as encircling the second gate electrode material layer 36, although the spacer 40 is illustrated as a plurality of layers. The spacer 40 may be formed using methods and materials analogous, equivalent or identical to the methods and materials that are used for forming the spacer 20.

FIG. 8 shows the results of sequentially patterning the first gate electrode material layer 34 to form a first gate electrode material layer 34′ and the gate dielectric 32 to form the gate dielectric 32′. The foregoing sequential patterning uses the second gate electrode material layer 36 and the spacer 40 as a mask.

FIG. 9 first shows a second spacer 42 located adjoining a sidewall of the spacer 40. The second spacer 42 within the second embodiment that is illustrated in FIG. 9 is otherwise generally analogous, equivalent or identical to the second spacer 22 within the first embodiment that is illustrated in FIG. 5.

FIG. 9 also shows a plurality of source and drain regions 44 located and formed within the semiconductor substrate 30 to provide a completed transistor structure. FIG. 9 further shows an inter-level dielectric (ILD) layer 46 located upon the resulting transistor structure and having a plurality of apertures located therein that expose the source and drain regions 44. FIG. 9 finally illustrates a plurality of vias 48 located within the plurality of apertures and contacting the plurality of source and drain regions 44.

Within the second embodiment as illustrated in FIG. 9: (1) the source and drain regions 44 are analogous, equivalent or identical with the source and drain regions 24 within the first embodiment as is illustrated in FIG. 5; (2) the inter-level dielectric (ILD) layer 46 is analogous, equivalent or identical to the inter-level dielectric (ILD) layer 26 within the first embodiment as is illustrated within FIG. 5; and (3) the plurality of vias 48 is analogous, equivalent or identical to the plurality of vias 28 within the first embodiment as is illustrated in FIG. 5.

FIG. 9 shows a schematic cross-sectional diagram of a semiconductor structure in accordance with a second embodiment of the invention. Similarly with the first embodiment of the invention, the semiconductor structure in accordance with the second embodiment also comprises a semiconductor device (i.e., a planar field effect transistor) that includes a gate electrode 34′/36 that has an inverted T shape. The inverted T shape for the gate electrode 34′/36 provides for a reduced gate electrode 34′/36 to via 48 capacitance or gate electrode 34′/36 to source and drain region 44 capacitance. Such a reduced gate electrode 34′/36 to via 48 capacitance or gate electrode 34′/36 to source and drain region 44 capacitance provides for enhanced performance of the transistor within the semiconductor structure of FIG. 9.

The preferred embodiment of the invention is illustrative of the invention rather than limiting of the invention. Revisions and modifications may be made to methods, materials, structures and dimensions of a semiconductor structure in accordance with the preferred embodiment of the invention, while still fabricating a semiconductor structure in accordance with the invention, further in accordance with the accompanying claims.

What is claimed is:

1. A semiconductor structure comprising a gate electrode located over a channel region that separates a plurality of source and drain regions within a semiconductor substrate, wherein the gate electrode has an inverted T shape.

2. The semiconductor structure of claim 1 wherein the semiconductor structure comprises a planar field effect transistor.

3. The semiconductor structure of claim 1 wherein:
a horizontal portion of the inverted T shape comprises a first gate electrode material; and
a vertical portion of the inverted T shape comprises a second gate electrode material different than the first gate electrode material.

4. The semiconductor structure of claim 3 wherein:
the first gate electrode material comprises a metal material; and
the second gate electrode material comprises a polysilicon material.

5. The semiconductor structure of claim 3 wherein:
the first gate electrode material comprises a metal material laminated upon a polysilicon material; and
the second gate electrode material comprises a polysilicon material.

6. A method for fabricating a semiconductor structure comprising:
providing a second gate electrode material layer aligned with a first gate electrode material layer different from the second gate electrode material layer over a semiconductor substrate;
thinning the second gate electrode material layer with respect to the first gate electrode material layer to provide an inverted T shaped gate electrode from a thinned second gate electrode material layer and the first gate electrode material layer; and
forming into the semiconductor substrate while using the inverted T shaped gate electrode as a mask a plurality of source and drain regions.

7. The method of claim 6 wherein the providing includes:
using the first gate electrode material layer that comprises a metal material; and
using the second gate electrode material layer that comprises a polysilicon material.

8. The method of claim 6 wherein the providing includes:
using the first gate electrode material layer that comprises a metal material laminated upon a polysilicon material; and
using the second gate electrode material layer that comprises a polysilicon material.

9. The method of claim 6 wherein the thinning uses an isotropic etch method that thins the second gate electrode material layer by lateral undercutting beneath a capping layer that is formed aligned upon the second gate electrode material layer.

10. The method of claim 9 wherein each side of the lateral undercutting beneath the capping layer is about one-third a linewidth of the capping layer.

11. The method of claim 6 further comprising forming an inter-level dielectric (ILD) layer covering the inverted T shaped gate electrode and the plurality of source and drain regions.

12. The method of claim 11 further comprising forming a plurality of vias through the inter-level dielectric (ILD) layer and contacting the plurality of source and drain regions.

13. The method of claim 12 wherein the inverted T shaped gate electrode provides a reduced gate electrode to via capacitance within the semiconductor structure.

14. A method for fabricating a semiconductor structure comprising:
providing a patterned second gate electrode material layer upon a first gate electrode material layer different from the patterned second gate electrode material layer over a semiconductor substrate;
forming a spacer adjoining the patterned second gate electrode material layer;
etching the first gate electrode material layer while using the patterned second gate electrode material layer and the spacer as a mask to provide an inverted T shaped gate electrode from the patterned second gate electrode material layer and a patterned first gate electrode material layer patterned from the first gate electrode material layer; and
forming into the semiconductor substrate while using at least the inverted T shaped gate electrode as a mask a plurality of source and drain regions.

15. The method of claim 14 wherein the providing includes:
using the first gate electrode material layer that comprises a metal material; and
using the second gate electrode material layer that comprises a polysilicon material.

16. The method of claim 14 wherein the providing includes:
using the first gate electrode material layer that comprises a metal material laminated upon a polysilicon material; and
using the second gate electrode material layer that comprises a polysilicon material.

17. The method of claim 14 wherein the forming the spacer uses an anisotropic etch method.

18. The method of claim 14 further comprising forming an inter-level dielectric (ILD) layer covering the inverted T shaped gate electrode and the plurality of source and drain regions.

19. The method of claim 18 further comprising forming a plurality of vias through the inter-level dielectric (ILD) layer and contacting the plurality of source and drain regions.

20. The method of claim 19 wherein the inverted T shaped gate electrode provides a reduced gate electrode to via capacitance within the semiconductor structure.
